(19) United States
(12) Patent Application Publication
(10) Pub. No.: US 2024/0395985 A1
(43) Pub. Date: Nov. 28, 2024

(54) DISPLAY DEVICE

(71) Applicant: AUO Corporation, Hsin-Chu (TW)

(72) Inventors: LI-WEI TSENG, Hsin-Chu (TW); SHAU-YU TSAI, Hsin-Chu (TW)

(21) Appl. No.: 18/669,604

(22) Filed: May 21, 2024

(30) Foreign Application Priority Data
May 25, 2023 (TW) 112119472

(51) Int. Cl. H01L 33/54; H01L 25/075

(52) U.S. Cl. CPC H01L 33/54; H01L 25/0753

(57) ABSTRACT

The present disclosure discloses a display device, including: a first display panel, including a first substrate, a first display layer, and a first optical layer; and a second display panel, including a second substrate, a second display layer, and a second optical layer. A first portion of the first end surface of the first display panel is located at an end of the first optical layer. A second portion of the second end surface of the second display panel is located at an end of the second optical layer. The first portion and the second portion are not in contact with each other and are separated at least by a predetermined gap. The first end surface and the second end surface are in direct or indirect contact or separated by an intermediate gap at a closest point. The predetermined gap is larger than the intermediate gap.

### CROSS REFERENCE TO RELATED APPLICATION

The present application claims the benefit of Taiwan Patent Application No. 112119472, filed on May 25, 2023. The entirety of the mentioned above patent application is hereby incorporated by reference herein and made a part of this specification.

### TECHNICAL FIELD

The present disclosure relates to a display device. Specifically, the present disclosure relates to a display device having a first optical layer and a second optical layer arranged adjacent to each other.

### BACKGROUND

A display device plays a very important role in modern society, and is increasingly applied in various fields. Due to the growing demand of users for large-sized display devices, splicing display panels have gradually become one of the main manners for implementing the large-sized display device. However, defects are prone to occur at a junction of the splicing display panels, and these defects are more likely to be exacerbated in the case of poor alignment or design. In addition, the defects may also be caused by different adaptabilities and differences between corresponding response and changes of components of the display device to an environmental condition during actual use. Therefore, under a specific environmental condition, the defects are more likely to occur at the junction in the splicing display panels. Based on the above, when the display device is in a dark state, the defects tend to be more significant and easier to detect, which deteriorates appearance and aesthetic of the entire display device. Therefore, it is necessary to develop a display device that splices display panels and that may reduce or avoid the above defects, to improve and maintain quality of the display device.

### SUMMARY

To solve the above problem, according to an embodiment of the present disclosure, a display device is provided, including: a first display panel, including a first substrate, a first display layer, and a first optical layer stacked sequentially, the first optical layer including at least one first optical film; and a second display panel, arranged adjacent to the first display panel in a first direction and including a second substrate, a second display layer, and a second optical layer stacked sequentially, the second optical layer including at least one second optical film. The first display panel and the second display panel respectively have a first end surface and a second end surface facing each other. A first portion of the first end surface is located at an end of the first optical layer. A second portion of the second end surface is located at an end of the second optical layer. Based on the above, the first portion and the second portion are not in contact with each other and are separated at least by a predetermined gap in the first direction. In addition, the first end surface and the second end surface are in direct or indirect contact or separated by an intermediate gap at a closest point in the first direction. The predetermined gap is larger than the intermediate gap.

The display device according to each embodiment of the present disclosure can reduce or avoid defects at a junction caused or deteriorated by differences between response and changes of components of a display device with splicing display panels under a specific environmental condition. Specifically, since the predetermined gap is located between the first optical layer and the second optical layer, the display device according to each embodiment of the present disclosure can reduce or avoid the defects to the optical films at the junction further caused or deteriorated due to a change of the environmental condition.

### BRIEF DESCRIPTION OF THE DRAWINGS

FIG. 1 is a schematic perspective view of a display device that is partially disassembled according to an embodiment of the present disclosure;

FIG. 2 is a schematic perspective view of a display device that is assembled according to an embodiment of the present disclosure;

FIG. 3 is a schematic sectional view of a junction of two adjacent display panels in a display device according to an embodiment of the present disclosure;

FIG. 4 is a schematic enlarged view of a local region of the display device in FIG. 3 according to an embodiment of the present disclosure;

FIG. 5 is a schematic sectional view of a junction of two adjacent display panels in a display device according to still another embodiment of the present disclosure;

FIG. 6 is a schematic sectional view of a junction of two adjacent display panels in a display device according to another embodiment of the present disclosure;

FIG. 7 is a schematic enlarged view of a local region of the display device in FIG. 6 according to an embodiment of the present disclosure;

FIG. 8 is a schematic sectional view of a junction of two adjacent display panels in a display device according to another embodiment of the present disclosure;

FIG. 9 is a schematic sectional view of a junction of two adjacent display panels in a display device according to an embodiment of the present disclosure;

FIG. 10 is a schematic sectional view of a junction of two adjacent display panels in a display device according to another embodiment of the present disclosure;

FIG. 11A is a schematic sectional view of a junction of connected display panels of a display device in an initial state according to an embodiment of the present disclosure;

FIG. 11B is a schematic sectional view of a junction of connected display panels of a display device in an after-test state according to an embodiment of the present disclosure;

FIG. 12A is a schematic top view of the junction of the connected display panels of the display device of FIG. 11A in the initial state;

FIG. 12B is a schematic top view of the junction of the connected display panels of the display device of FIG. 11B in the after-test state;

FIG. 13A is a schematic sectional view of a junction of connected display panels of a display device in an initial state according to another embodiment of the present disclosure;

FIG. 13B is a schematic sectional view of a junction of connected display panels of a display device in an after-test state according to another embodiment of the present disclosure;

FIG. 14A is a schematic top view of the junction of the connected display panels of the display device of FIG. 13A in the initial state;

FIG. 14B is a schematic top view of the junction of the connected display panels of the display device of FIG. 13B in the after-test state;

FIG. 15A is an actual top-view photo of the connected display panels of the display device of FIG. 14A in the initial state from a macroscopic perspective; and

FIG. 15B is an actual top-view photo of the connected display panels of the display device of FIG. 14B in the after-test state from a macroscopic perspective.

### DETAILED DESCRIPTION

The following describes various embodiments. A person of ordinary skill in the art can easily understand the spirit and the principle of the present disclosure with reference to the descriptions in conjunction with the accompanying drawings. However, although some specific embodiments are specifically described in this specification, these embodiments are merely examples and should not be considered restrictive or exhaustive on each aspect. Therefore, various variations and modifications made to the present disclosure without departing from the spirit and the principle of the present disclosure are apparent and readily achievable by a person of ordinary skill in the art.

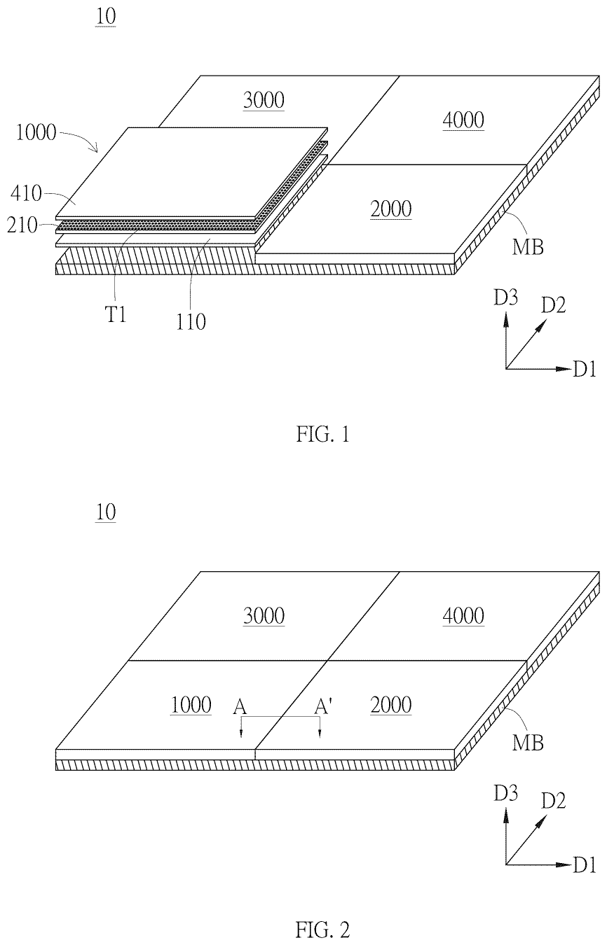

Referring to FIG. 1 and FIG. 2, according to an embodiment of the present disclosure, a display device 10 that splices a plurality of display panels to present a large display surface is proposed. Specifically, the display device 10 may include a first display panel 1000, a second display panel 2000, a third display panel 3000, and a fourth display panel 4000 that are spliced with each other in a first direction D1 and a second direction D2 to form a complete plane. Based on the above, the display panels may be arranged on a mounting base MB. The mounting base MB is, but is not limited to, for example, an assembly frame, a support frame, an arrangement carrier, a wall, or a ground. A specific quantity and arrangement of display panels in this embodiment are merely examples, and another embodiment is not limited thereto. Based on the above, the following gives detailed descriptions according to this embodiment, and a person of ordinary skill in the art can make corresponding adjustments accordingly for application to other embodiments.

Based on the above, according to this embodiment, a structure of each display panel may be briefly described with the first display panel 1000 that is exemplarily disassembled as an example. Specifically, the first display panel 1000 may include a first substrate 110, a first display layer 210, and a first optical layer 410 stacked sequentially in a third direction D3. Another display panel may have a same or similar configuration. According to some embodiments, the first display layer 210 may be defined with display units (for example, pixels), and the first display panel 1000 may change or adjust the content to be displayed based on the first display layer 210. For example, the first display layer 210 may include a plurality of first light-emitting units T1, and may respectively control each first light-emitting unit T1 to be turned on/off to adjust the display unit, thereby changing and displaying the content to be displayed.

According to some embodiments, the first light-emitting unit T1 may be a light-emitting diode (LED), a micro LED, a mini LED, or another light-emitting unit arranged based on a package on board (POB) mode or a chip on board (COB) mode. Specifically, during arrangement based on the POB mode, each first light-emitting unit T1 may be a single encapsulated body including a plurality of light-emitting chips (for example, a plurality of LEDs, micro LEDs, or mini LEDs), and may be used as a display unit. During arrangement based on the COB mode, each first light-emitting unit T1 may be a single light-emitting chip (for example, the LED, the micro LED, or the mini LED), and a group of first light-emitting units T1 (for example, a red LED, a green LED, and a blue LED) that are configured sequentially may be entirely used as a display unit. However, the above is merely an example, and according to each embodiment of the present disclosure, the display unit capable of implementing display and an arrangement mode thereof are not limited thereto.

Based on the above, the first substrate 110 may support the first display layer 210, and may include other components or structures of the first display panel 1000. For example, according to some embodiments, the first substrate 110 may include a printed circuit board, a glass substrate, or another component or structure. Based on the above, a person of ordinary skill in the art may arrange components or structures contained in the first substrate 110 based on a requirement and a design, and details are not described herein again.

Then, continuing to refer to FIG. 1, the first optical layer 410 arranged on the first display layer 210 may include at least one first optical film, so that an optical property of light emitted through the first display layer 210 may be modified, adjusted, or improved, or an exterior optical property of the entire first display panel 1000 and the appearance of the entire first display panel 1000 may be further improved or modified. Based on the above, according to some embodiments, the first optical film may include one or more of an anti-glare coating, an anti-reflective coating, a circular polarizer, a linear polarizer, a quarter-wave plate, a micro-structured optical film, a bonding adhesive, and an ultra-black treatment film. However, these are merely examples, and another embodiment of the present disclosure is not limited thereto.

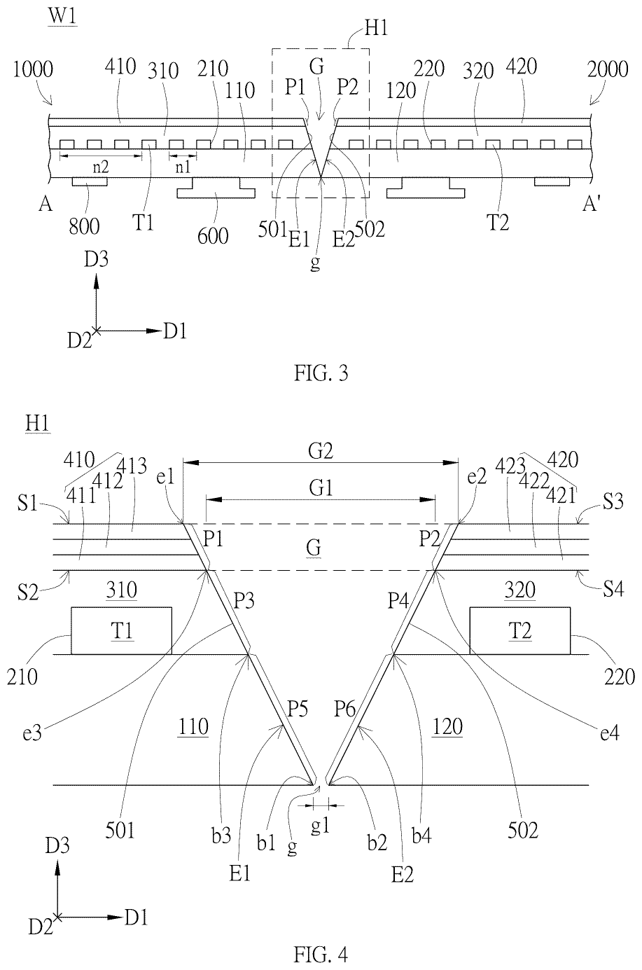

As shown in FIG. 2, according to this embodiment, a complete large-sized display device 10 may be implemented by splicing a plurality of display panels such as the first display panel 1000, the second display panel 2000, the third display panel 3000, and the fourth display panel 4000. Based on the above, the following further exemplarily describes in detail a specific configuration architecture of the display device 10 with reference to FIG. 3 obtained along a section line A-A′ in FIG. 2.

As described above, another display panel may have a configuration the same as or similar to that of the first display panel 1000. For example, referring to FIG. 3, the second display panel 2000 arranged adjacent to the first display panel 1000 in the first direction D1 may include a second substrate 120, a second display layer 220, and a second optical layer 420 stacked sequentially. In addition, each display panel of the display device 10 may further include a positioning piece 600 (for example, but not limited to, locking or magnetically attaching to the mounting base MB) configured to assemble or position other components, a circuit element 800 (for example, an integrated circuit (IC)), and/or another component or structure. Based on the above, according to different embodiments of the present disclosure, a person of ordinary skill in the art may additionally arrange the corresponding positioning piece 600 and/or circuit component 800, or another structural layer or functional layer based on the requirement and the design, and details are not described herein again. In addition, according to some embodiments, to further implement encapsulation, leveling, and connection on the first display layer 210 or the second display layer 220, a first encapsulation adhesive layer 310 may be further provided between the first optical layer 410 and the first display layer 210, and a second encapsulation adhesive layer 320 may be further provided between the second optical layer 420 and the second display layer 220. Specifically, according to some embodiments, the first encapsulation adhesive layer 310 and the second encapsulation adhesive layer 320 may have at least partial light transmittance (for example, have at least light transmittance of 10% in a case of a thickness of 0.4 mm), so that the light emitted through the first display layer 210 and the second display layer 220 may at least partially pass through the first encapsulation adhesive layer 310 and the second encapsulation adhesive layer 320. However, other embodiments of the present disclosure are not limited thereto.

According to this embodiment, the first display panel 1000 and the second display panel 2000 may respectively have a first end surface E1 and a second end surface E2 facing each other. A first portion P1 of the first end surface E1 may be located at an end of the first optical layer 410. A second portion P2 of the second end surface E2 may be located at an end of the second optical layer 420. Based on the above, the first portion P1 and the second portion P2 are not in contact with each other and may be separated at least by a predetermined gap G in the first direction D1. In addition, the first end surface E1 and the second end surface E2 are in direct or indirect contact or may be separated by an intermediate gap g at a closest point in the first direction D1. If there is the intermediate gap g, the predetermined gap G between the first portion P1 and the second portion P2 is larger than the intermediate gap g. In other words, the first portion P1 of the first end surface E1 and the second portion P2 of the second end surface E2 that are not in contact with each other are not the closest point between the first end surface E1 and the second end surface E2, and the predetermined gap G is larger than a gap at the closest point.

It should be noted that in this specification and the corresponding accompanying drawings, for ease of description and identification, the predetermined gap G that is actually small is drawn in an exaggerative scale for description. In fact, a scale and a relative proportion of each component drawn in the accompanying drawings in the present application may both be adjusted or exaggerated for brevity or ease of description and identification, and a person of ordinary skill in the art should know that a size of each component, a gap, or the like in each embodiment of the present disclosure is not limited to the specific scale and relative proportion of drawing herein.

Based on the above, according to some embodiments, the predetermined gap G may not be larger than 0.15 mm. In addition, according to some embodiments, the predetermined gap G may be larger than 0.03 mm. However, this is merely an example, and other embodiments of the present disclosure are not limited thereto.

As shown in FIG. 3, according to some embodiments, the first display layer 210 may include the plurality of first light-emitting units T1 arranged on the first substrate 110, and the second display layer 220 may include a plurality of second light-emitting units T2 arranged on the second substrate 120. In the first direction D1, a pixel spacing is located between adjacent display units defined based on a configuration of the first light-emitting units T1 and/or the second light-emitting units T2, and the predetermined gap G may not be larger than 12% of the pixel spacing. For example, according to some embodiments, referring to FIG. 3, the first display layer 210 may be arranged based on the POB mode to include the first light-emitting units T1 encapsulating a plurality of light-emitting chips, and the second display layer 220 may be arranged based on the POB mode to include the second light-emitting units T2 encapsulating the plurality of light-emitting chips. Based on the above, in this case, each of the first light-emitting unit T1 and/or the second light-emitting unit T2 is used as a display unit. Therefore, in the first direction D1, a spacing n1 between adjacent first light-emitting units T1 or adjacent second light-emitting units T2 is a pixel spacing n1, and the predetermined gap G may not be larger than 12% of the pixel spacing n1.

In addition, according to some other embodiments, referring to FIG. 3, if the first display layer 210 is arranged based on the COB mode in a manner that each first light-emitting unit is a first light-emitting unit T1 of a light-emitting chip of specific light (for example, but not limited to, a red LED, a green LED, or a blue LED), and the second display layer 220 is arranged based on the COB mode in a manner that each second light-emitting unit is a second light-emitting unit T2 of a light-emitting chip of specific light (for example, but not limited to, a red LED, a green LED, or a blue LED), in the first direction D1, a spacing n2 between the first light-emitting units T1 of same specific light or the second light-emitting units T2 of same specific light may be a pixel spacing n2. For example, the red LED, the green LED, and the blue LED may be sequentially and repeatedly configured on the first substrate 110 and the second substrate 120 to form the first display layer 210 and the second display layer 220. A spacing n2 between a red LED and a next red LED that are separated may be the pixel spacing n2. The predetermined gap G may not be larger than 12% of the pixel spacing n2.

Based on the above, according to some embodiments, the predetermined gap G may be adjusted corresponding to a configuration mode of the display unit such as the first light-emitting unit T1 and the second light-emitting unit T2 in a display layer such as the first display layer 210 and the second display layer 220, the pixel spacing, a property such as a coefficient of thermal expansion (CTE) of the optical film used, and the like. As described above, according to some embodiments, the predetermined gap G may be smaller than the pixel spacing, for example, may not be larger than 12% of the pixel spacing, so that the arrangement of the predetermined gap G can reduce or avoid impact on a display state of finally splicing display panels.

Then, referring to FIG. 3 and FIG. 4 enlarging a region H1 in FIG. 3, according to an implementation W1 in this embodiment, the first end surface E1 may have a first inclined surface 501, and the first inclined surface 501 may at least partially extend to the first portion P1, so that the first optical layer 410 is retracted in the first direction D1 relative to at least a part of the first substrate 110. Similarly, the second end surface E2 may have a second inclined surface 502, and the second inclined surface 502 may at least partially extend to the second portion P2, so that the second optical layer 420 is retracted in the first direction D1 relative to at least a part of the second substrate 120.

Based on the above, according to this embodiment, a front surface S1 of the first optical layer 410 opposite to the first substrate 110 may be retracted in the first direction D1 relative to a bottom surface S2 of the first optical layer 410 facing the first substrate 110. For example, the first optical layer 410 may include a first optical film 411, a first optical film 412, and a first optical film 413, and the first optical film 413 far away from the first substrate 110 may be retracted in the first direction D1 relative to the first optical film 411 closer to the first substrate 110. Similarly, a front surface S3 of the second optical layer 420 opposite to the second substrate 120 may be retracted in the first direction D1 relative to a bottom surface S4 of the second optical layer 420 facing the second substrate 120. For example, the second optical layer 420 may include a second optical film 421, a second optical film 422, and a second optical film 423, and the second optical film 423 far away from the second substrate 120 may be retracted in the first direction D1 relative to the second optical film 421 closer to the second substrate 120.

In addition, a fifth portion P5 of the first end surface E1 may be located at an end of the first substrate 110, and the first inclined surface 501 may further extend from the first portion P1 to at least a part of the fifth portion P5. Similarly, a sixth portion P6 of the second end surface E2 may be located at an end of the second substrate 120, and the second inclined surface 502 may further extend from the second portion P2 to at least a part of the sixth portion P6. For example, a third portion P3 of the first end surface E1 may be located at an end of the first encapsulation adhesive layer 310, and the first inclined surface 501 may sequentially extend from the first portion P1 and the third portion P3 to the fifth portion P5. In addition, a fourth portion P4 of the second end surface E2 may be located at an end of the second encapsulation adhesive layer 320, and the second inclined surface 502 may sequentially extend from the second portion P2 and the fourth portion P4 to the sixth portion P6.

Based on the above, according to this embodiment, when the first inclined surface 501 further extends to the fifth portion P5, and the second inclined surface 502 further extends to the sixth portion P6, a distance between the first inclined surface 501 and the second end surface E2 at the first portion P1 may be greater than that at the fifth portion P5, and a distance between the second inclined surface 502 and the first end surface E1 at the second portion P2 may be greater than that at the sixth portion P6.

For example, a gap length G2 may be located between a top edge e1 of the first portion P1 opposite to the first substrate 110 and a top edge e2 of the second portion P2 opposite to the second substrate 120, and a gap length G1 may be located between a bottom edge e3 of the first portion P1 facing the first substrate 110 and a bottom edge e4 of the second portion P2 facing the second substrate 120. Based on the above, the predetermined gap G between the first portion P1 and the second portion P2 may fall within a range from the gap length G1 to the gap length G2, and this range may be larger than a gap between the fifth portion P5 and the sixth portion P6. For example, the length G1 and the length G2 of the predetermined gap G and the range between them may be larger than a minimum gap length g1 of the intermediate gap g.

According to some embodiments, a maximum gap between the first end surface E1 and the second end surface E2 in the first direction D1 may be located between a top edge e1 of the first portion P1 opposite to the first substrate 110 and a top edge e2 of the second portion P2 opposite to the second substrate 120. In other words, a gap length G2 may be the maximum gap between the first end surface E1 and the second end surface E2 in the first direction D1. However, the above is merely an example, and other embodiments of the present disclosure are not limited thereto. For example, according to another embodiment, both a maximum gap and a minimum gap between the first end surface E1 and the second end surface E2 in the first direction D1 may be located between the fifth portion P5 and the sixth portion P6. For example, there may be another inclined surface or structural surface, so that both the maximum gap and the minimum gap between the first end surface E1 and the second end surface E2 in the first direction D1 are located between the fifth portion P5 and the sixth portion P6 (or the fifth portion P5 and the sixth portion P6 may be in direct or indirect contact with each other). In addition, the maximum gap and the minimum gap between the first end surface E1 and the second end surface E2 in the first direction D1 may alternatively be located between the first end surface E1 and the second end surface E2 other than the fifth portion P5 and the sixth portion P6. Based on the above, there may be various structural implementations according to each embodiment of the present disclosure as long as the predetermined gap G between the first portion P1 and the second portion P2 is larger than the intermediate gap g between the first end surface E1 and the second end surface E2 at the closest point (that is, the minimum gap or a contact position between the first end surface E1 and the second end surface E2).

In addition, according to some embodiments, as shown in FIG. 4, the intermediate gap g between the first end surface E1 and the second end surface E2 at the closest point may be located between a bottom edge b1 of the fifth portion P5 opposite to the first optical layer 410 and a bottom edge b2 of the sixth portion P6 opposite to the second optical layer 420. Alternatively, a bottom edge b1 of the fifth portion P5 opposite to the first optical layer 410 and a bottom edge b2 of the sixth portion P6 opposite to the second optical layer 420 may be in direct or indirect contact with each other. However, this is merely an example, and other embodiments of the present disclosure are not limited thereto. For example, the intermediate gap g between the first end surface E1 and the second end surface E2 at the closest point may alternatively be located between a top edge b3 of the fifth portion P5 facing the first optical layer 410 and a top edge b4 of the sixth portion P6 facing the second optical layer 420. Alternatively, a top edge b3 of the fifth portion P5 facing the first optical layer 410 and a top edge b4 of the sixth portion P6 facing the second optical layer 420 may alternatively be in direct or indirect contact with each other. Based on the above, according to each embodiment of the present disclosure, provided that not being located between the first portion P1 and the second portion P2, a position of the closest point between the first end surface E1 and the second end surface E2 are not limited to these examples.

In addition, in FIG. 3 and FIG. 4, although the first inclined surface 501 actually extends along the entire first end surface E1, and the second inclined surface 502 actually extends along the entire second end surface E2, this is merely an example. Based on the above, according to another embodiment of the present disclosure, the first inclined surface 501 may extend along a part of the first end surface E1, and the second inclined surface 502 may extend along a part of the second end surface E2.

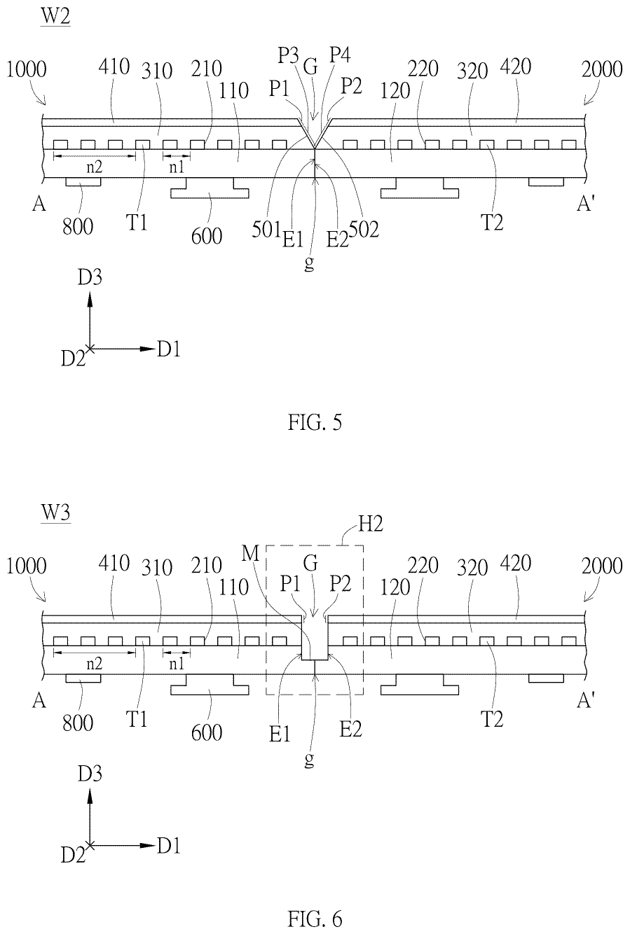

For example, referring to another implementation W2 shown in FIG. 5, the first inclined surface 501 extends only from the first portion P1 to the third portion P3, and the second inclined surface 502 extends only from the second portion P2 to the fourth portion P4. Based on the above, in this embodiment, the third portion P3 and the fourth portion P4 may be at least partially not in contact with each other or not in contact at all in the first direction D1.

As described above, according to some embodiments of the present disclosure, the predetermined gap G may be formed using inclined surfaces extending at least to the first portion P1 and the second portion P2, and the inclined surfaces are used so that the predetermined gap G between the first portion P1 and the second portion P2 is larger than the intermediate gap g between the first end surface E1 and the second end surface E2 at the closest point. Specifically, as shown in FIG. 3 to FIG. 5, the first inclined surface 501 may have a negative slope, and the second inclined surface 502 may have a positive slope. Therefore, relative to a boundary between the first end surface E1 and the second end surface E2, the first portion P1 may have a longer distance than other portions of the first end surface E1, or the second portion P2 may have a longer distance than other portions of the second end surface E2.

In addition, referring to FIG. 6, according to still another implementation W3, the predetermined gap G may not be formed by providing the inclined surfaces of the first end surface E1 or the second end surface E2. In detail, according to this embodiment, a step difference is formed between the first portion P1 and another portion of the first end surface E1, and a step difference is formed between the second portion P2 and another portion of the second end surface E2, so that a stepped structure M is formed between the first display panel 1000 and the second display panel 2000. Therefore, the predetermined gap G between the first portion P1 and the second portion P2 may be formed even through no inclined surfaces are provided (for example, but not limited to, flat surfaces are provided).

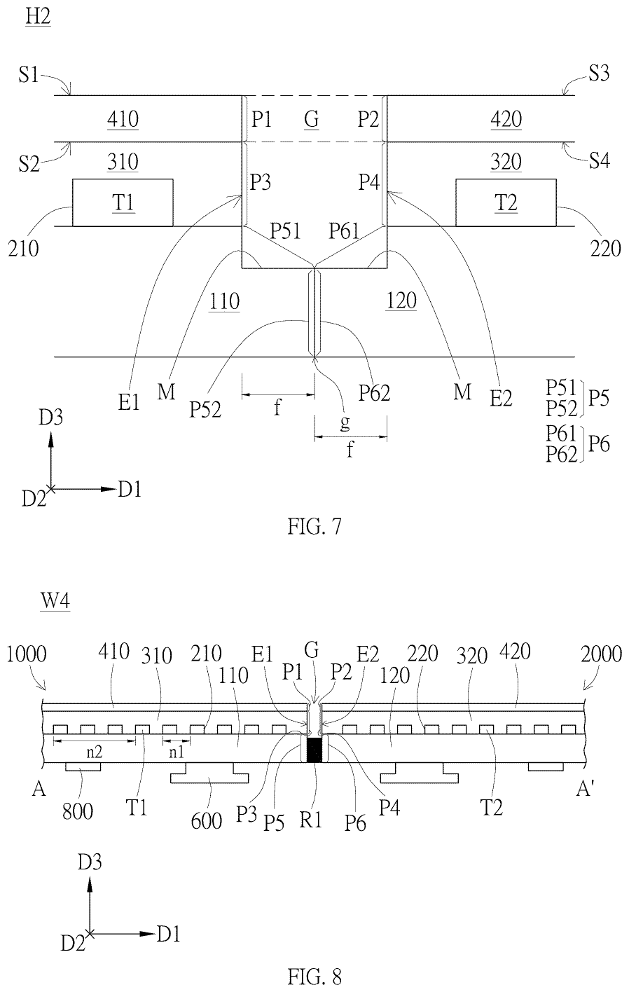

Specifically, referring to FIG. 7 of a schematic enlarged view of a region H2 in FIG. 6, the first end surface E1 located at the end of the first substrate 110 may have, for example, a first sub-portion P51 and a second sub-portion P52 of the fifth portion P5, and the second end surface E2 located at the end of the second substrate 120 may have, for example, a first sub-portion P61 and a second sub-portion P62 of the sixth portion P6. There may be a step difference f between the first portion P1 and the second sub-portion P52 in the first direction D1, so that the first end surface E1 at least partially forms a stepped structure M. In other words, there may be the step difference f between the first portion P1 and at least a part of the fifth portion P5 in the first direction D1, so that the first end surface E1 at least partially forms the stepped structure M. Similarly, there may also be a step difference f between the second portion P2 and the second sub-portion P62 in the first direction D1, so that the second end surface E2 at least partially forms a stepped structure M. In other words, there may be the step difference f between the second portion P2 and at least a part of the sixth portion P6 in the first direction D1, so that the second end surface E2 at least partially forms the stepped structure M.

Based on the above, in this case, the first end surface E1 may have a vertical surface with the step difference, and the second end surface E2 may have a vertical surface with the step difference. Therefore, an inclination angle for cutting does not need to be designed and arranged in a manufacturing procedure for machining and cutting the first end surface E1 and the second end surface E2, which simplifies the manufacturing procedure for machining.

In addition, although the first end surface E1 and the second end surface E2 herein have the stepped structure M symmetrically, other embodiments of the present disclosure are not limited thereto. For example, the first end surface E1 and the second end surface E2 may alternatively have step differences f of different magnitudes. Alternatively, the first end surface E1 or the second end surface E2 may alternatively form a multi-stepped structure M or the like.

Next, referring to FIG. 8, according to still another implementation W4, a first spacer R1 may be included between the first display panel 1000 and the second display panel 2000. For example, the first spacer R1 may be at least partially connected to a portion of the first end surface E1 and the second end surface E2 other than the first portion P1 and the second portion P2, for example, a fifth portion P5 and a sixth portion P6, and the first end surface E1 and the second end surface E2 may be in indirect contact through the first spacer R1. Therefore, the predetermined gap G between the first portion P1 and the second portion P2 may be formed based on the first spacer R1 arranged between the first end surface E1 and the second end surface E2. Therefore, cutting or grinding of the first end surface E1 and/or the second end surface E2 can be reduced. For example, no additional inclined surfaces need to be arranged, so that a machining procedure for the first display panel 1000 and the second display panel 2000 and corresponding possible defects in the machining procedure can be reduced or avoided.

In addition, referring to FIG. 9, according to yet another implementation W5, more than just a first spacer R1 may be included between the first display panel 1000 and the second display panel 2000. Specifically, the first spacer R1 may be at least partially connected to a portion of the first end surface E1 other than the first portion P1, for example, a fifth portion P5. In addition, a second spacer R2 may be at least partially connected to a portion of the second end surface E2 other than the second portion P2, for example, a sixth portion P6. The first spacer R1 may be pressed against the second spacer R2. Therefore, the predetermined gap G between the first portion P1 and the second portion P2 may be formed based on the first spacer R1 and the second spacer R2 that are arranged between the first end surface E1 and the second end surface E2. Therefore, even though the first end surface E1 and/or the second end surface E2 are arranged to be a flat surface formed through aligned cutting (for example, but not limited to, the first portion P1, the third portion P3, and the fifth portion P5 are flatly cut in an aligned manner in the third direction D3, and the second portion P2, the fourth portion P4, and the sixth portion P6 are flatly cut in the aligned manner in the third direction D3), according to this embodiment, the predetermined gap G may still be formed between the first portion P1 and the second portion P2. In this way, as described above, a machining procedure for the first display panel 1000 and the second display panel 2000 and possible corresponding defects in the machining procedure can be reduced or avoided.

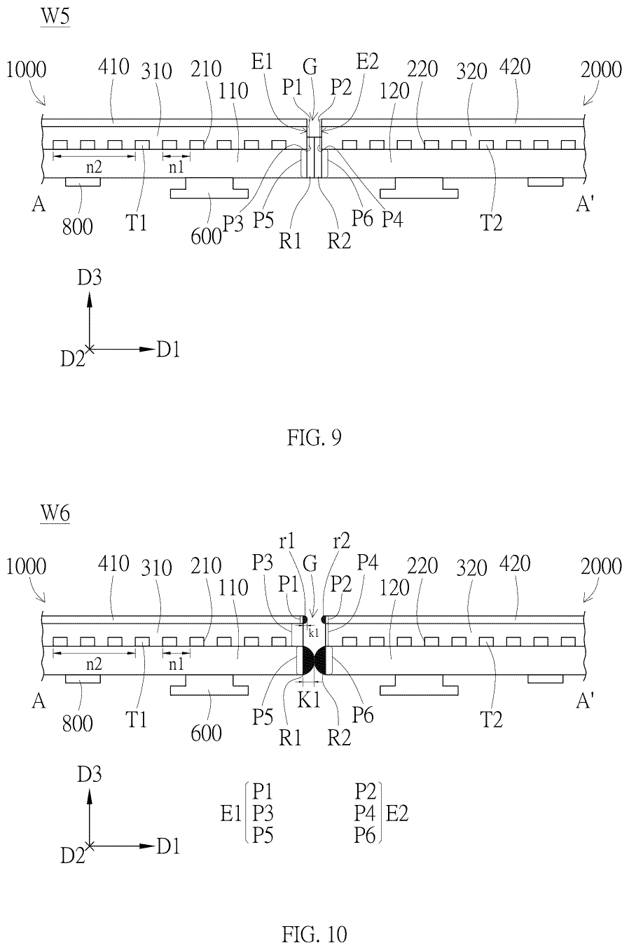

Moreover, referring to FIG. 10, according to another implementation W6, in addition to providing the first spacer R1 and the second spacer R2, the display device may further selectively include a first additional spacer r1 at the first end surface E1 and/or a second additional spacer r2 at the second end surface E2. For example, as shown in FIG. 10, according to this embodiment, the display device may further selectively include the first additional spacer r1 at least partially connected to the first portion P1, and further selectively include the second additional spacer r2 at least partially connected to the second portion P2. In addition, according to another embodiment, the first additional spacer r1 may further extend to be at least partially connected to the third portion P3, and the second additional spacer r2 may further extend to be at least partially connected to the fourth portion P4. Alternatively, according to some other embodiments, the first additional spacer r1 may be only at least partially connected to the third portion P3 but not connected to the first portion P1, and the second additional spacer r2 may be only at least partially connected to the fourth portion P4 but not connected to the second portion P2, and so on. Based on the above, as shown in the implementation W6, the first additional spacer r1 and/or the second additional spacer r2 may be arranged based on requirements of various functions. For example, the first additional spacer r1 and the second additional spacer r2 may be arranged to cover or modify defects of cut surfaces of the first portion P1 and the second portion P2 respectively. However, this is merely an example, and a position, a size, a quantity, a function, or a use of the additional spacers are substantially not limited thereto.

Based on the above, according to this embodiment, the first spacer R1 may protrude more to the second end surface E2 than the first additional spacer r1 in the first direction D1, and/or the second spacer R2 may protrude more to the first end surface E1 than the second additional spacer r2 in the first direction D1. Therefore, even though the first additional spacer r1 and the second additional spacer r2 are arranged, the first additional spacer r1 and the second additional spacer r2 are not pressed against each other. In other words, the first spacer R1 may be pressed against the second spacer R2 at a junction of the first display panel 1000 and the second display panel 2000, so that the first additional spacer r1 and the second additional spacer r2 are separated from each other.

For example, when the first end surface E1 and the second end surface E2 are each flush in the vertical direction, a thickness K1 of the first spacer R1 in the first direction D1 may be greater than a thickness kl of the first additional spacer r1 in the first direction D1, so that the first spacer R1 protrudes more to the second end surface E2 than the first additional spacer r1 in the first direction D1. A similar configuration is used for the second end surface E2. However, this is merely an example, and according to another embodiment of the present disclosure, the first end surface E1 and the second end surface E2 may be not flush. Therefore, an adjustment may be made based on a surface shape and a protrusion degree of the first end surface E1, so that the first spacer R1 protrudes more to the second end surface E2 than the first additional spacer r1 in the first direction D1. The thickness K1 of the first spacer R1 is not necessarily greater than the thickness kl of the first additional spacer r1. Similarly, a similar adjustment may be made on the second end surface E2. Based on the above, provided that the first spacer R1 protrudes more and/or the second spacer R2 protrudes more so that the first spacer R1 and the second spacer R2 are pressed against each other, and the first additional spacer r1 and the second additional spacer r2 are not pressed against each other, implementable configurations of other embodiments of the present disclosure are not limited thereto.

According to some embodiments, the first spacer R1, the second spacer R2, the first additional spacer r1, and the second additional spacer r2 may be components such as an adhesive tape, a dispensed adhesive, or a gasket. In addition, the spacer or the additional spacer may be configured on a single side (arranged only on the first end surface E1 or the second end surface E2) or configured on both sides (arranged on the first end surface E1 and the second end surface E2 respectively). Based on the above, according to each embodiment of the present disclosure, if conforming to the principle of the present disclosure, quantities, positions, forms, or patterns of the spacer and the additional spacer that may be used are not limited to the examples shown in this specification and the accompanying drawings.

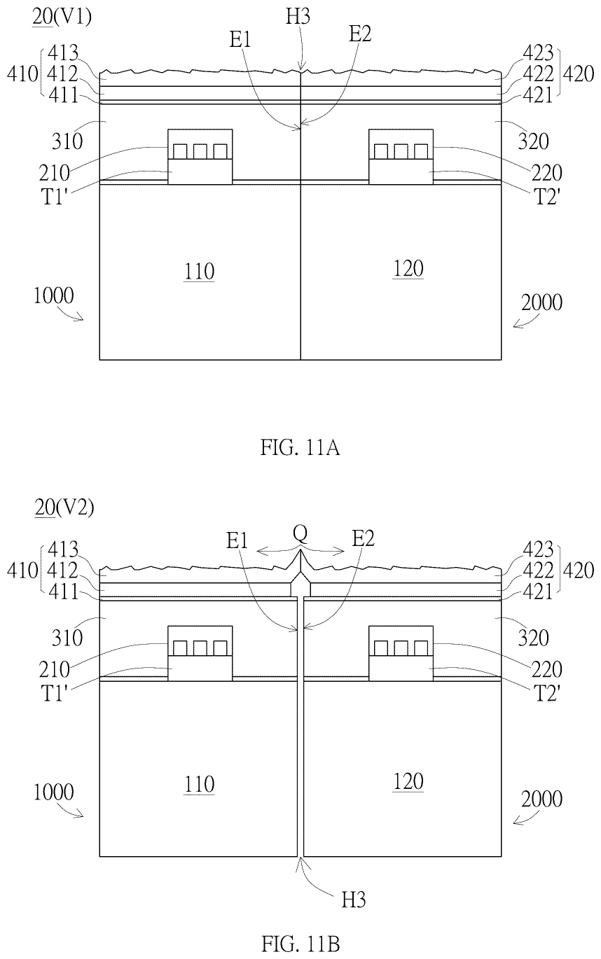

Next, changes of the display device under a specific environmental condition are further described with reference to FIG. 11A and FIG. 11B.

Based on the above, referring to an initial state V1 in FIG. 11A, a display device 20 according to an embodiment may have a structure similar to that of the display device 10. However, the predetermined gap larger than the intermediate gap between the first end surface E1 and the second end surface E2 at the closest point is not formed between the first optical layer 410 and the second optical layer 420 in a junction region H3 between the first display panel 1000 and the second display panel 2000. In other words, the predetermined gap is not particularly formed between the first optical layer 410 and the second optical layer 420. According to this embodiment, the first optical layer 410 and the second optical layer 420 may further be in pressed contact with each other.

As shown in FIG. 11A, the first display layer 210 may include a first light-emitting unit T1′ as a display unit, and the second display layer 220 may include a second light-emitting unit T2′ as a display unit. The first light-emitting unit T1′ and the second light-emitting unit T2′ may be display units in a single package on board (POB) packaging mode formed by integrating and encapsulating LEDs emitting light in different colors, for example, a red LED, a green LED, and a blue LED. However, other embodiments of the present disclosure are not limited thereto.

Based on the above, referring to an after-test state V2 in FIG. 11B, after the first optical layer 410 and the second optical layer 420 of the display device 20 are subjected to test conditions of a temperature of 60° C. and a humidity of 90%, the optical films contained therein may be changed due to the high temperature and the high humidity, causing defects or deteriorating of original defects in the junction region H3 between the first display panel 1000 and the second display panel 2000. Specifically, in a case of temperature and humidity changes, the optical film which is originally thin and highly tensile may undergo more significant changes in properties, shape, length, or the like compared to other components. Therefore, even though being designed and cut into an expected shape or pattern in the initial state V1, the optical film may still unexpectedly protrude, retract, and even become stripped from other components after an environmental test. In addition, since the first optical layer 410 and the second optical layer 420 each may include a plurality of optical films, and the optical films may respond differently to the temperature change and the humidity change from each other, interlayer stripping or an interlayer length difference may occur in the first optical layer 410 and the second optical layer 420.

For example, referring to FIG. 11B, according to this embodiment, the first optical film 413 and the second optical film 423 may thermally expand with the high temperature and/or absorb water to expand with the high humidity, so as to stretch and protrude, and the first optical film 412 and the second optical film 422 may be shrunk with the high temperature and/or absorb water to be curled up and deformed with the high humidity, so as to be tightened and retracted. Based on the above, different optical films may have differences in a coefficient of thermal expansion (CTE), water absorption degrees, deformation properties, and the like, so that the optical films may be changed relative to other components or relative to each other after subjected to the specific environmental condition, which may cause adverse defects or further manifest a splicing line at a junction between adjacent display panels. For example, according to this embodiment, the first optical film 413 and the second optical film 423 that protrude may be further pressed against and squeezed by each other, resulting in a conflict of stress Q. As a result, there are various defects, for example, protrusion, roughness, unevenness, or interlayer stripping of the optical films, and even a distance between the first end surface E1 and the second end surface E2 may be further expanded.

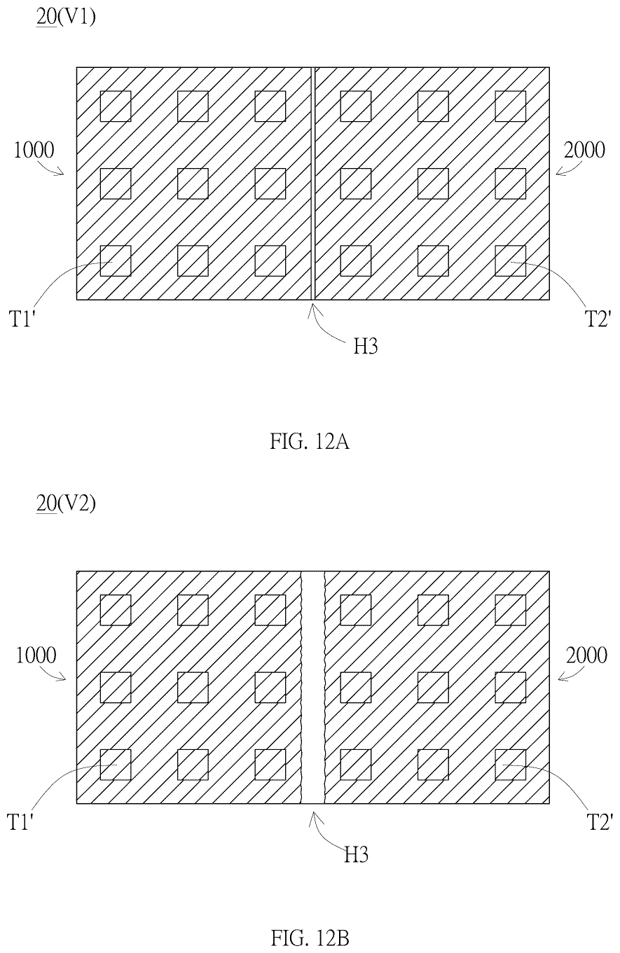

Please refer to FIG. 12A and FIG. 12B, which are respectively schematic microscopic top views of the display device 20 corresponding to FIG. 11A and FIG. 11B. According to this embodiment, the junction region H3 between the first display panel 1000 and the second display panel 2000 is more apparent in the after-test state V2. The junction region H3 may reflect defects such as stripping of the optical film, which may enlarge, for example, a perceptible white portion, thus deteriorating the appearance and aesthetic of the display device 20 in a dark state. As described above, referring to FIG. 11A to FIG. 12B, the unexpected defects such as squeezing, raising, and even interlayer stripping of the first optical layer 410 and the second optical layer 420 in the junction region H3 make the junction region H3, which is expected to be not apparent, apparent.

Based on the above, to reduce perception of the splicing line at the junction between the adjacent display panels, the adjacent display panels such as the first display panel 1000 and the second display panel 2000 may be closer in the initial state V1. However, in the after-test state V2 (reflecting that the display device is subjected to the specific environmental condition), the optical films at the junction may be more likely to produce defects, and the splicing line is more likely to be perceived. As a result, the appearance and aesthetic are deteriorated.

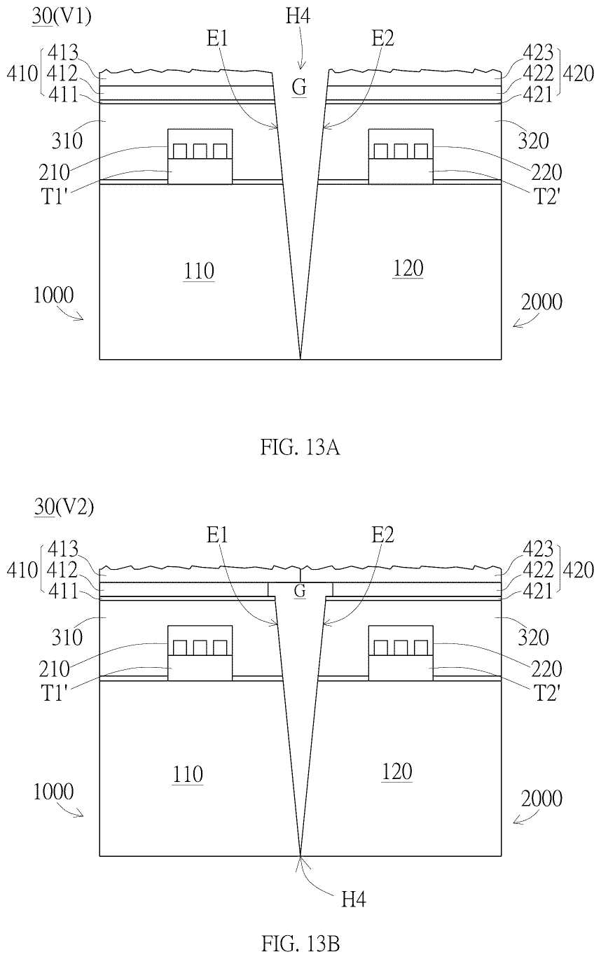

In contrast, referring to the initial state V1 in FIG. 13A, a display device 30 according to still another embodiment of the present disclosure may have a configuration the same as or similar to the implementation W1 in FIG. 3. The predetermined gap G may be located between the first optical layer 410 and the second optical layer 420 in a junction region H4 between the first display panel 1000 and the second display panel 2000. According to this embodiment, a maximum length of the predetermined gap G may be approximately 0.15 mm, and the first substrate 110 and the second substrate 120 may be in contact with each other. Based on the above, although the predetermined gap G is formed between the first optical layer 410 and the second optical layer 420, the junction region H4 has portions of the first end surface E1 and the second end surface E2 that are relatively close to and even pressed against each other. Therefore, the portions that are relatively close to and even pressed against each other may be observed through the predetermined gap G, so that the arrangement of the predetermined gap G of the display device 30 may not significantly add a gap splicing line that is perceptible.

Based on the above, referring to the after-test state V2 in FIG. 13B, the predetermined gap G is formed in advance, so that impact of a possible change between the first optical layer 410 and the second optical layer 420 on the junction region H4 can be reduced or lowered. For example, the first optical film 413 of the first optical layer 410 and the second optical film 423 of the second optical layer 420 may thermally expand with the high temperature and/or absorb water to expand with the high humidity, so as to stretch and protrude. Based on the above, according to this embodiment, the conflict of the stress Q caused by mutual pressing and squeezing of the first optical film 413 and the second optical film 423 that protrude can be reduced or avoided, and occurrence of defects such as raising or interlayer stripping of the optical films or deterioration of similar related defects, can also be further reduced or avoided.

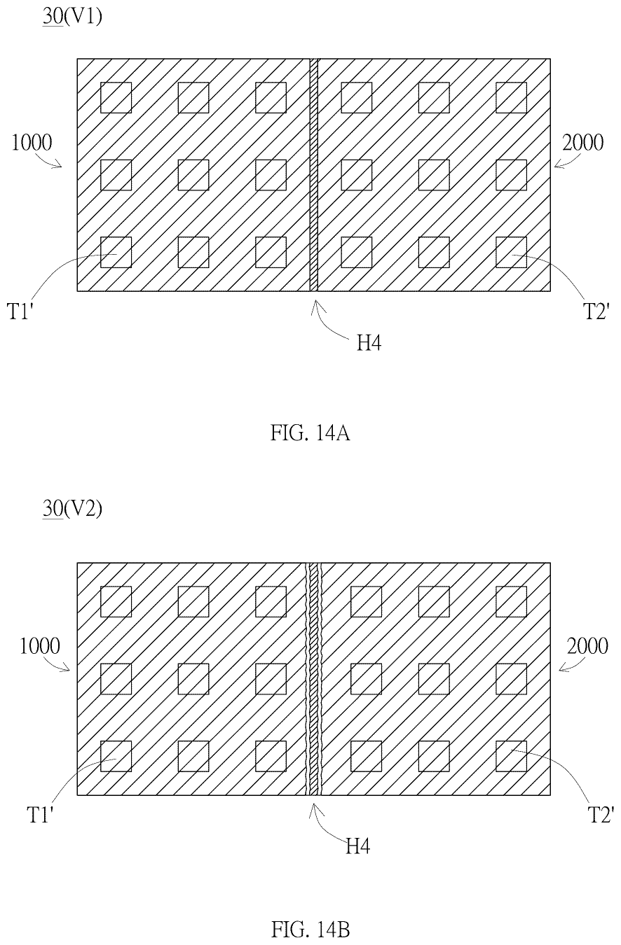

Please refer to FIG. 14A and FIG. 14B, which are respectively schematic microscopic top views of the display device 30 corresponding to FIG. 13A and FIG. 13B. It can be learned that the junction region H4 between the first display panel 1000 and the second display panel 2000 is less apparent than the junction region H3 of the display device 20 in the after-test state V2. In detail, in the after-test state V2, a white portion of the junction region H4 reflecting the defects is enlarged less than that of the junction region H3 of the display device 20 reflecting the defects. It is worth noting that, in the dark state, the impact of a bright line, such as a white portion, on the overall appearance is greater than that of a dark line on the overall appearance. Therefore, according to this embodiment, the white portion reflected by the change (for example, squeezing or stripping) of the optical film may be reduced to keep the appearance and aesthetic of the display device 30 in the dark state at a specific level even under a high-temperature and high-humidity environment.

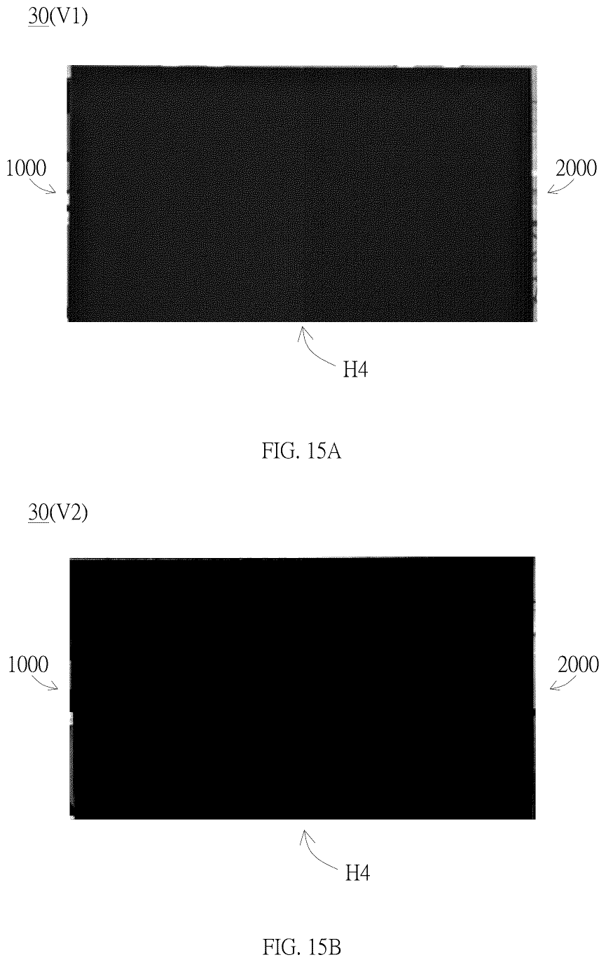

For example, please refer to FIG. 15A and FIG. 15B, which are actual macroscopic top views of a configuration implementation of the display device 30 corresponding to FIG. 14A and FIG. 14B, respectively. It can be learned that the predetermined gap G in the junction region H4 between the first display panel 1000 and the second display panel 2000 does not bring significant impact on the appearance and aesthetic in the initial state V1. Therefore, according to this embodiment, the predetermined gap G between the first optical layer 410 and the second optical layer 420 can greatly improve the appearance and aesthetic of the display device 30 in the after-test state V2 after a reliability test (reflecting the specific environmental condition), without affecting the appearance and aesthetic in the initial state V1. Based on the above, the display device 30 according to this embodiment proves that deterioration of the junction region H4 between the splicing first display panel 1000 and the splicing second display panel 2000 undergo a similar environmental condition can be reduced or avoided, and therefore, the tolerance and the service life of the display device 30 can be improved.

As described above, according to this embodiment, even though the optical film may protrude in the after-test state V2, the predetermined gap formed between the first optical layer 410 and the second optical layer 420 can effectively reduce or avoid excessive squeezing between the protruding optical films, so as to reduce or avoid defects such as interlayer stripping and raising, or at least reduce degrees of such changes (for example, the raising is gentle). Therefore, significant defects or changes that are macroscopically perceptible can be significantly reduced or avoided.

In addition, as described above, the predetermined gap may be smaller than the pixel spacing between the display units such as the first light-emitting unit T1′ and the second light-emitting unit T2′, so that the impact of the predetermined gap on the appearance and aesthetic in the bright state in which light is emitted for display can be reduced to an ignorable level.

In summary, the display device according to each embodiment of the present disclosure can reduce or avoid the defects caused by changes of each optical film of the splicing display panels in length, shape, and the like under an environmental condition such as a specific temperature or a specific humidity. Therefore, occurrence of the defects or deterioration of the defects in the junction region between the splicing display panels after the display device is subjected to the specific environmental condition can be reduced or avoided, which enhances the tolerance of the entire display device and improves the appearance and aesthetic of the entire display device.

The above is merely some preferred embodiments of the present disclosure. It should be noted that various variations and modifications may be made to the present disclosure without departing from the spirit and the principle of the present disclosure. A person of ordinary skill in the art should know that the present disclosure is defined by the scope of the appended claims, and various possible variations in line with the intent of the present disclosure, such as replacements, combinations, modifications, and transformations, shall fall within the scope defined by the appended claims of the present disclosure.

### REFERENCE NUMERALS

10, 20, 30: display device
110: first substrate
120: second substrate
210: first display layer
220: second display layer
310: first encapsulation adhesive layer
320: second encapsulation adhesive layer
410: first optical layer
411: first optical film
412: first optical film
413: first optical film
420: second optical layer
421: second optical film
422: second optical film
423: second optical film
501: first inclined surface
502: second inclined surface
600: positioning piece
800: circuit element
1000: first display panel
2000: second display panel
3000: third display panel
4000: fourth display panel
b1: bottom edge
b2: bottom edge
b3: top edge
b4: top edge
D1: first direction
D2: second direction
D3: third direction
E1: first end surface
E2: second end surface
e1: top edge
e2: top edge
e3: bottom edge
e4: bottom edge
f: step difference
G: predetermined gap
G1: gap length
G2: gap length
g: intermediate gap
g1: gap length
H1: region
H2: region
H3: junction region
H4: junction region
M: stepped structure
MB: mounting base
n1, n2: spacing
P1: first portion
P2: second portion
P3: third portion
P4: fourth portion
P5: fifth portion
P6: sixth portion
P51: first sub-portion
P52: second sub-portion
P61: first sub-portion
P62: second sub-portion
Q: stress
R1: first spacer
R2: second spacer
r1: first additional spacer
r2: second additional spacer
S1: front surface
S2: bottom surface
S3: front surface
S4: bottom surface
T1: first light-emitting unit
T2: second light-emitting unit
T1′: first light-emitting unit
T2′: second light-emitting unit
V1: initial state
V2: after-test state
W1, W2, W3. W4, W5, W6: implementation

What is claimed is:

1. A display device, comprising:
a first display panel, comprising a first substrate, a first display layer, and a first optical layer stacked sequentially, the first optical layer comprising at least one first optical film; and
a second display panel, arranged adjacent to the first display panel in a first direction and comprising a second substrate, a second display layer, and a second optical layer stacked sequentially, the second optical layer comprising at least one second optical film, wherein
the first display panel and the second display panel respectively have a first end surface and a second end surface facing each other, a first portion of the first end surface is located at an end of the first optical layer, and a second portion of the second end surface is located at an end of the second optical layer; and
the first portion and the second portion are not in contact with each other and are separated at least by a predetermined gap in the first direction, the first end surface and the second end surface are in direct or indirect contact or separated by an intermediate gap at a closest point in the first direction, and the predetermined gap is larger than the intermediate gap.

2. The display device according to claim 1, wherein a first encapsulation adhesive layer is provided between the first optical layer and the first display layer, and a second encapsulation adhesive layer is provided between the second optical layer and the second display layer;
a third portion of the first end surface is located at an end of the first encapsulation adhesive layer, and a fourth portion of the second end surface is located at an end of the second encapsulation adhesive layer; and
the third portion and the fourth portion are at least partially not in contact with each other in the first direction.

3. The display device according to claim 1, wherein the first display layer comprises a plurality of first light-emitting units arranged on the first substrate; and
in the first direction, a pixel spacing is located between adjacent display units defined based on a configuration of the first light-emitting unit, and the predetermined gap is not larger than 12% of the pixel spacing.

4. The display device according to claim 1, wherein the predetermined gap is not larger than 0.15 mm.

5. The display device according to claim 1, wherein the predetermined gap is larger than 0.03 mm.

6. The display device according to claim 1, wherein a fifth portion of the first end surface is located at an end of the first substrate; and
the display device further comprises a first spacer at least partially connected to the fifth portion, and the first end surface and the second end surface are in indirect contact through the first spacer.

7. The display device according to claim 6, further comprising a first additional spacer at least partially connected to the first end surface, wherein
the first spacer protrudes more to the second end surface than the first additional spacer in the first direction.

8. The display device according to claim 7, wherein a thickness of the first spacer in the first direction is greater than a thickness of the first additional spacer in the first direction.

9. The display device according to claim 1, wherein the first end surface has a first inclined surface; and the first inclined surface at least partially extends to the first portion, so that the first optical layer is retracted in the first direction relative to at least a part of the first substrate.

10. The display device according to claim 1, wherein a fifth portion of the first end surface is located at an end of the first substrate, and the first end surface has a first inclined surface extending from the first portion to at least a part of the fifth portion; and
a distance between the first inclined surface and the second end surface at the first portion is greater than that at the fifth portion.

11. The display device according to claim 1, wherein a front surface of the first optical layer opposite to the first substrate is retracted in the first direction relative to a bottom surface of the first optical layer facing the first substrate.

12. The display device according to claim 1, wherein a fifth portion of the first end surface is located at an end of the first substrate; and the first portion has a step difference with at least a part of the fifth portion in the first direction, so that the first end surface at least partially forms a stepped structure.

13. The display device according to claim 1, wherein a maximum gap between the first end surface and the second end surface in the first direction is located between a top edge of the first portion opposite to the first substrate and a top edge of the second portion opposite to the second substrate.

14. The display device according to claim 1, wherein a fifth portion of the first end surface is located at an end of the first substrate, a sixth portion of the second end surface is located at an end of the second substrate, and the intermediate gap is located between the fifth portion and the sixth portion, or the fifth portion and the sixth portion are in direct or indirect contact with each other.

15. The display device according to claim 14, wherein the intermediate gap is located between a bottom edge of the fifth portion opposite to the first optical layer and a bottom edge of the sixth portion opposite to the second optical layer, or the bottom edge of the fifth portion opposite to the first optical layer and the bottom edge of the sixth portion opposite to the second optical layer are in direct or indirect contact with each other.
